(19) United States
(12) Patent Application Publication
(10) Pub. No.: US 2017/0301735 A1
(43) Pub. Date: Oct. 19, 2017

(54) CHARGE INTEGRATING DEVICES AND RELATED SYSTEMS

(71) Applicant: General Electric Company, Schenectady, NY (US)

(72) Inventors: Jie Jerry Liu, Niskayuna, NY (US); Gautam Parthasarathy, Niskayuna, NY (US); Ri-An Zhao, Niskayuna, NY (US); Kwang Hyup An, Rexford, NY (US)

(21) Appl. No.: 15/132,542

(22) Filed: Apr. 19, 2016

(51) Int. Cl. H01L 27/30; H01L 51/00; G01T 1/20

(52) U.S. Cl. CPC H01L 27/308; G01T 1/2018; H01L 51/0046

(57) ABSTRACT

An organic charge integrating device is presented. The organic charge integrating device includes a thin film transistor (TFT) array, a first electrode layer disposed on the TFT array, an organic photoactive layer disposed on the first electrode layer, and a second electrode layer disposed on the organic photoactive layer. The organic photoactive layer has a thickness in a range from about 700 nanometers to about 3 microns. An organic x-ray detector is presented. An imaging system including the organic x-ray detector is also presented.

### BACKGROUND

Embodiments of the present disclosure generally relate to charge integrating devices. More particularly, embodiments of the present disclosure relate to organic charge integrating devices for example, organic x-ray detectors.

Charge integrating devices may be used in a variety of imaging applications such as molecular and optical imaging systems. Charge integrating devices such as digital x-ray detectors have potential applications for low cost digital radiography as well as for rugged, light-weight and portable detectors. The charge integrating devices fabricated with organic photodiodes may have an increased fill factor and potentially higher quantum efficiency.

Generally, charge integrating devices may be manufactured by disposing continuous OPD layers onto a thin film transistor (TFT) array, resulting in a continuous OPD layer configuration. OPDs including thin photoactive layers (10 nanometers to 300 nanometers) are typically suggested for achieving improved performance. Particularly, conventional knowledge in these technology domains such as in photodiode and solar cell devices, suggests that thinner the photoactive layer, higher the quantum efficiency of the device. Accordingly, it might has been assumed that charge integrating devices including OPDs having thin organic photoactive layers would outperform charge integrating devices including OPDs having thick organic photo active layers.

However, one of the technical challenges for charge integrating devices such as organic x-ray detectors for applications in medical and industrial non-destructive tests, may be poor quality of the thin photoactive layers. High quality photoactive layers may be desirable for improved performance of the organic charge integrating devices.

Therefore, there is a continuing need for improved charge integrating devices such as organic x-ray detectors.

### BRIEF DESCRIPTION

In one aspect of the specification, an organic charge integrating device is presented. The organic charge integrating device includes a thin film transistor (TFT) array, a first electrode layer disposed on the TFT array, an organic photoactive layer disposed on the first electrode layer, and a second electrode layer disposed on the organic photoactive layer. The organic photoactive layer has a thickness in a range from about 700 nanometers to about 3 microns.

In one aspect of the specification, an organic x-ray detector includes a thin film transistor (TFT) array, a first electrode layer disposed on the TFT array, an organic photoactive layer disposed on the first electrode layer, a second electrode layer disposed on the organic photoactive layer, and a scintillator layer disposed on the second electrode layer. The organic photoactive layer includes a fullerene or a fullerene derivative having a carbon cluster of at least 60 carbon atoms, and has a thickness in a range from about 700 nanometers to about 3 microns.

One aspect of the specification presents an imaging system including the organic charge integrating device.

These and other features, embodiments, and advantages of the present disclosure may be understood more readily by reference to the following detailed description.

### DRAWINGS

These and other features, aspects, and advantages of the present disclosure will become better understood when the following detailed description is read with reference to the accompanying drawings in which like characters represent like parts throughout the drawings, wherein:

FIG. 1 is a schematic of an organic charge integrating device, in accordance with one embodiment of the invention;

FIG. 2 is a schematic of an organic charge integrating device, in accordance with one embodiment of the invention;

FIG. 3 is a schematic of an organic charge integrating device, in accordance with one embodiment of the invention;

FIG. 4 is a schematic of an organic charge integrating device, in accordance with one embodiment of the invention;

FIG. 5 is a graph showing quantum efficiency (QE) of an organic charge integrating device as a function of thickness of an organic photoactive layer; and

FIG. 6 is a schematic of an imaging system, in accordance with one embodiment of the invention.

### DETAILED DESCRIPTION

In the following specification and the claims, the singular forms “a”, “an” and “the” include plural referents unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about” and “substantially”, is not limited to the precise value specified. In some instances, the approximating language may correspond to the precision of an instrument for measuring the value.

Unless defined otherwise, technical and scientific terms used herein have the same meaning as is commonly understood by one of skill in the art to which this invention belongs. The terms “comprising,” “including,” and “having” are intended to be inclusive, and mean that there may be additional elements other than the listed elements. The terms “first”, “second”, and the like, as used herein do not denote any order, quantity, or importance, but rather are used to distinguish one element from another.

As used herein, the term “layer” refers to a material disposed on at least a portion of an underlying surface in a continuous or discontinuous manner. Further, the term “layer” does not necessarily mean a uniform thickness of the disposed material, and the disposed material may have a uniform or a variable thickness. As used herein, the term “disposed on” refers to layers disposed directly in contact with each other or indirectly by having intervening layers there between, unless otherwise specifically indicated.

In the present disclosure, when a layer is being described as “on” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

As used herein, the terms “photoactive layer” and “organic photoactive layer” refer to an organic layer that is capable of generating electric charges in response to or controlled by incident electromagnetic radiation. The organic photoactive layer may also be referred to as an organic photoelectric layer. A device that includes an organic photoactive layer may be referred to as an organic photoactive device. In some embodiments, the organic photoactive layer may be a bulk, hetero-junction organic photodiode layer that absorbs light, generates photo-excited charges that is, excitons (electron-hole pairs), separates the charges (holes and electrons) upon exciton dissociation, and transports electric charge to the opposing contact layers (electrode layers). In some embodiments, the organic photoactive layer comprises a donor material and an acceptor material.

As used herein, the terms “charge integrating device” and “organic charge integrating device” refer to an organic photoactive device that measures total charges per channel accumulated during a pre-set settling time in response to the irradiation of electromagnetic radiation for a time duration. The measurement of accumulated charges may be performed by reading-out data (that is, accumulated charges in channels) by device electronics. As used herein, the term “channel” refers to one pixel, a row of pixels or a column of pixels depending on a read-out layout.

An organic charge integrating device, generally, performs one imaging cycle in a frame time. One imaging cycle includes irradiating the organic charge integrating device with electromagnetic radiation and reading-out data (that is, accumulated charges in channels). As used herein, the term “frame time” refers to a time duration for performing one imaging cycle. In some embodiments, a frame time includes a time period of irradiating electromagnetic radiation to the organic charge integration device, a read-out time, and settling times before and after irradiating electromagnetic radiation to the organic charge integrating device. Depending on the device configuration and the application, the frame time may be greater than 1 microsecond per channel and less than 5 minutes per channel.

A read-out time refers to a total time taken for reading-out data in a read-out layout (that includes channels) of the organic charge integrating device. A read-out time for an organic charge integrating device may be in a range from about 10 microseconds to about 500 milliseconds. Settling times before and after irradiating electromagnetic radiation onto the organic charge integrating device may be in a range from about 100 milliseconds to about 500 milliseconds. A time period for irradiating electromagnetic radiation on to the organic charge integration device may be in a range from about 10 milliseconds to about 500 milliseconds.

In some embodiments, the charge integrating device is a light imager that measures accumulated charges in response to visible photons. In some embodiments, the charge integrating device is an x-ray detector that includes a scintillator material which converts x-rays to visible photons, and measures the accumulated charges in response to incident x-rays.

Some embodiments of the present disclosure are directed to an organic charge integrating device, such as organic light imagers and organic x-ray detectors. The organic charge integrating device includes a thin film transistor (TFT) array, a first electrode layer disposed on the TFT array, an organic photoactive layer disposed on the first electrode layer, and a second electrode layer disposed on the organic photoactive layer. The organic photoactive layer has a thickness in a range from about 700 nanometers to about 3 microns.

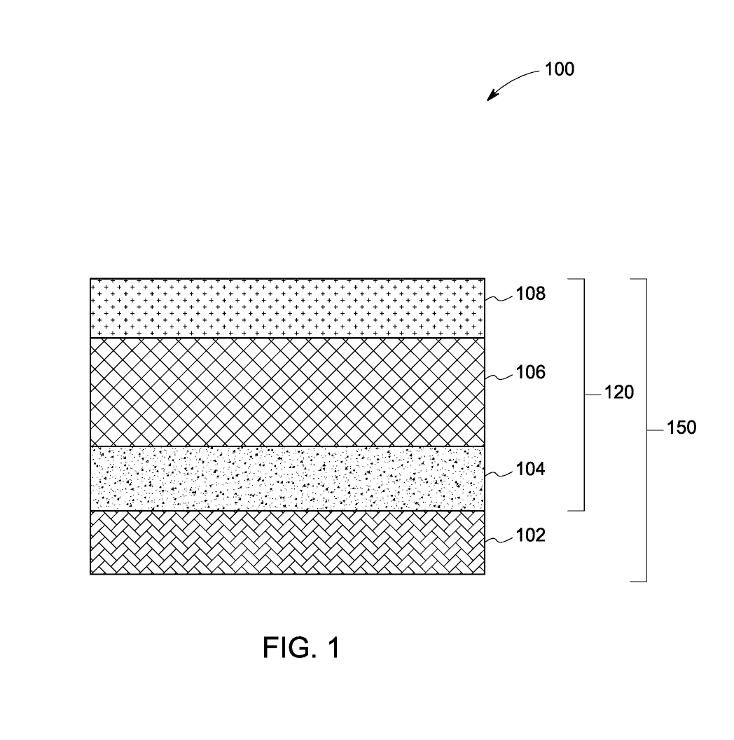

A schematic representation of an organic charge integrating device 100 is shown in FIGS. 1-4. The organic charge integrating device 100 includes a TFT array 102, a first electrode layer 104, a second electrode layer 108, and an organic photoactive layer 106 interposed between the first electrode layer 104 and the second electrode layer 108. The organic photoactive layer 106 may also be referred to as an “active layer.” In some embodiments, the organic photoactive layer 106 may be patterned. The first electrode layer 104, the organic photoactive layer 106, and the second electrode layer 108 may form an organic photodiode (OPD) 120 disposed on the TFT array 102.

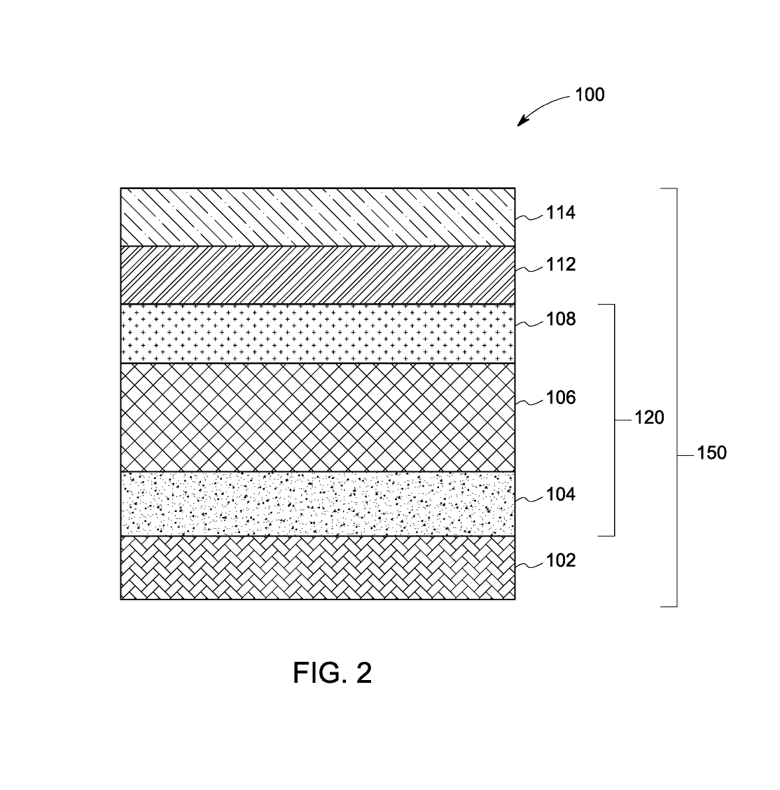

Referring to FIGS. 1-4, the organic photodiode 120 disposed on the TFT array 102 may form an organic light imager 150. In some embodiments, as shown in FIGS. 1-2, the organic charge integrating device 100 is an organic light imager.

In some embodiments, the organic light imager 150 may further include one or more layers, for example a planarization layer and a barrier layer disposed on the second electrode layer 108. One or both of the planarization layer and the barrier layer may provide protection to the organic photodiode 120. FIG. 2 illustrates some embodiments where an organic light imager 150 includes a planarization layer 112 disposed on the second electrode 108 and a barrier layer 114 disposed on the planarization layer 112.

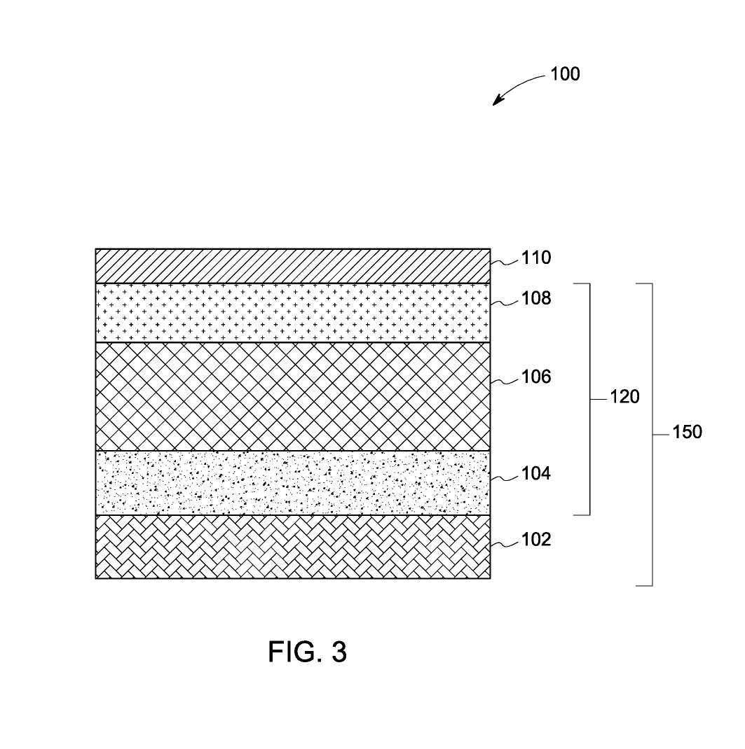

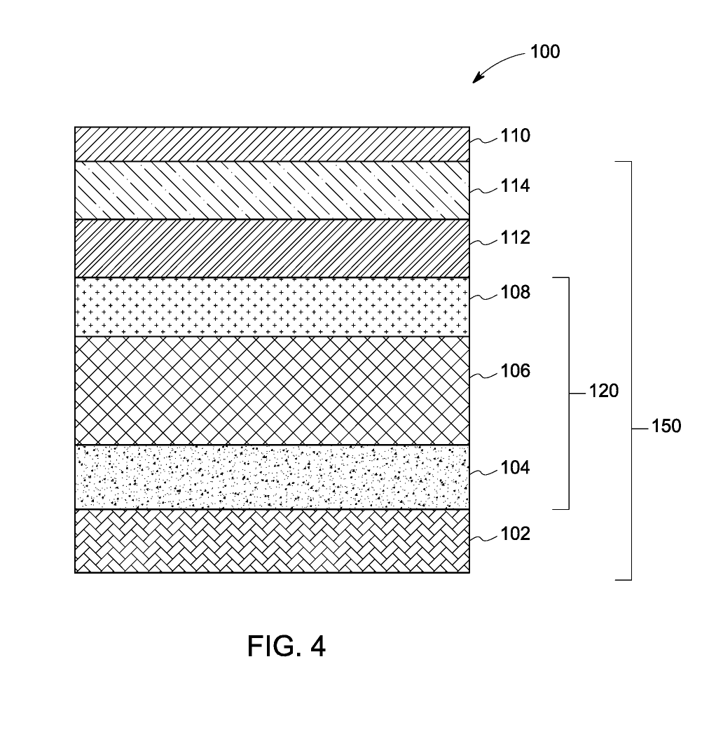

In some embodiments, as shown in FIGS. 3-4, the organic charge integrating device 100 further includes a scintillator layer 110 disposed on the organic light imager 150. The scintillator layer 110 generates light that irradiates the organic photodiode 120. In some embodiments, the scintillator layer 110 is excited by impinging x-ray radiation, and generates visible light. In these embodiments, the organic charge integrating device 100 is an organic x-ray detector.

FIG. 3 illustrates an embodiment where the scintillator layer 110 is disposed on the second electrode layer 108. In embodiments where the organic light imager 150 includes one or both of the planarization layer 112 and the barrier layer 114, the scintillator layer 110 is disposed on the planarization layer 112 or the barrier layer 114. The planarization layer 112 may provide a smooth surface on the organic photodiode 120 prior to the deposition of the scintillator layer 110. FIG. 4 illustrates an embodiment of an organic charge integrating device 100 that includes the planarization layer 112 and the barrier layer 114 interposed between the second electrode layer 108 and the scintillator layer 110. As illustrated, the planarization layer 112 is disposed on the second electrode layer 108 and the barrier layer 114 is interposed between the planarization layer 112 and the scintillator layer 110.

Referring to FIGS. 1-4, depending on the application and variations in design, the organic photodiode 120 may include a single organic layer or may include multiple organic layers. In some embodiments, the organic photodiode 120 may further include one or more charge blocking layers, for example, an electron blocking layer and a hole blocking layer (not shown in Figures). In some embodiments, one or more charge blocking layers include a crosslinkable polymer. In some embodiments, one or more charge blocking layers include a crosslinkable compound including, for example an epoxy or acrylate. In some embodiments, an electron blocking layer may be disposed between the first electrode layer 104 and the organic photoactive layer 106. In some embodiments, a hole blocking layer may be disposed between the organic photoactive layer 106 and the second electrode layer 108. Further, the organic photodiode 120 may be directly disposed on the TFT array 102, or the organic charge integrating device 100 may include one or more layers disposed between the organic photodiode 120 and the TFT array 102.

In one embodiment, the first electrode layer 104 functions as a cathode and the second electrode layer 108 as an anode. In another embodiment, the first electrode layer 104 functions as an anode and the second electrode layer 108 as a cathode. Suitable anode materials include, but are not limited to, metals such as Al, Ag, Au, and Pt; metal oxides such as indium tin oxide (ITO), indium zinc oxide (IZO), and zinc oxide (ZnO); and organic conductors such as p-doped conjugated polymers like poly(3,4-ethylenedioxythiophene) (PEDOT). Suitable cathode materials include transparent conductive oxides (TCO) and thin films of metals such as gold and silver. Examples of suitable TCO include ITO, IZO, aluminum zinc oxide (AZO), fluorinated tin oxide (FTO), tin oxide (SnO₂), titanium dioxide (TiO₂), ZnO, indium zinc oxide (In—Zn—O series), indium gallium oxide, gallium zinc oxide, indium silicon zinc oxide, indium gallium zinc oxide, or combinations thereof.

The TFT array 102 may be a two dimensional array of passive or active pixels, which stores charges for read out by electronics. In some embodiments, the passive or active pixels include a storage capacitor that may modulate the capacity of charge storage. The storage capacitor may be referred to as “pixel capacitor”, and these terms may be used interchangeably throughout the specification. The TFT array 102 may be disposed on a layer formed of amorphous silicon, poly-crystalline silicon, an amorphous metal oxide, or organic semiconductors. In some embodiments, the TFT array includes a silicon TFT array, an oxide TFT array, an organic TFT, or combinations thereof. Suitable examples of the amorphous metal oxides include zinc oxide, zinc tin oxide, indium oxides, indium zinc oxides (In—Zn—O series), indium gallium oxides, gallium zinc oxides, indium silicon zinc oxides, and indium gallium zinc oxides (IGZO). IGZO materials include InGaO₃(ZnO)ₘ where m is <6 and InGaZnO₄. Suitable examples of the organic semiconductors for the TFT array include, but are not limited to, conjugated aromatic materials, such as rubrene, tetracene, pentacene, perylenediimides, tetracyanoquinodimethane and polymeric materials such as polythiophenes, polybenzodithiophenes, polyfluorene, polydiacetylene, poly(2,5-thiophenylene vinylene), poly(p-phenylene vinylene), and derivatives thereof.

The TFT array 102 may be disposed on a substrate (not shown). Suitable substrate materials include glass, ceramics, plastics, metals or combinations thereof. The substrate may be present as a rigid sheet such as a thick glass, a thick plastic sheet, a thick plastic composite sheet, and a metal plate; or a flexible sheet, such as, a thin glass sheet, a thin plastic sheet, a thin plastic composite sheet, and metal foil. Examples of suitable materials for the substrate include glass, which may be rigid or flexible; plastics such as polyethylene terephthalate, polybutylene phthalate, polyethylene naphthalate, polystyrene, polycarbonate, polyether sulfone, polyallylate, polyimide, polycycloolefin, norbornene resins, and fluoropolymers; metals such as stainless steel, aluminum, silver and gold; metal oxides such as titanium oxide and zinc oxide; and semiconductors such as silicon. In certain embodiments, the substrate includes a polycarbonate.

The organic photoactive layer 106 may include a blend of a donor material and an acceptor material. In some embodiments, more than one donor or acceptor may be included in the blend. Further, the HOMO/LUMO levels of the donor and acceptor materials may be compatible with that of the first and second electrode layers (104, 108) in order to allow efficient charge extraction without creating an energetic barrier.

As used herein, the terms “donor material”, “donor phase” and “donor” may be used interchangeably throughout the specification; and the terms “acceptor material”, “acceptor phase” and “acceptor” may be used interchangeably throughout the specification.

Suitable donor materials include low bandgap polymers having LUMO ranging from about 1.9 eV to about 4.9 eV and HOMO ranging from about 2.9 eV to about 7 eV. In some embodiments, the donor material has LUMO in a range from 2.5 eV to 4.5 eV, and in certain embodiments, from 3.0 eV to 4.5 eV. In some embodiments, the donor material has HOMO in a range from 4.0 eV to 6 eV, and in certain embodiments, from 4.5 eV to 6 eV. In some embodiments, the donor material has HOMO greater than or equal to 5.0 eV. The low band gap polymers include conjugated polymers and copolymers composed of units derived from substituted or unsubstituted monoheterocyclic and polyheterocyclic monomers such as thiophene, fluorene, phenylenvinylene, carbazole, pyrrolopyrrole, and fused heteropolycyclic monomers containing the thiophene ring, including, but not limited to, thienothiophene, benzodithiophene, benzothiadiazole, pyrrolothiophene monomers, and substituted analogs thereof. In some embodiments, the low band gap polymers include units derived from substituted or unsubstituted thienothiophene, benzodithiophene, benzothiadiazole, carbazole, isothianaphthene, pyrrole, benzo-bis(thiadiazole), thienopyrazine, fluorene, thiadiazolequinoxaline, or combinations thereof. In the context of the low band gap polymers described herein, the term “units derived from” means that the units include monoheterocyclic and polyheterocyclic group, without regard to the substituents present before or during the polymerization; for example, “the low band gap polymers include units derived from thienothiophene” means that the low band gap polymers include divalent thienothiophenyl groups. Examples of suitable materials for use as low bandgap polymers, in some embodiments, include copolymers derived from substituted or unsubstituted thienothiophene, benzodithiophene, benzothiadiazole, carbazole monomers, or combinations thereof, such as poly[[4,8-bis[(2-ethyl hexyl)oxy]benzo[1,2-b:4,5-b′]dithiophene-2,6-diyl][3-fluoro-2-[2-ethylhexyl)carbonyl] thieno[3,4-b]thiophenediyl (PTB7); 2,1,3-benzothiadiazole-4,7-diyl[4,4-bis(2-ethylhexyl)-4H-cyclopenta[2,1-b:3,4-b]dithiophene-2,6-diyl (PCPDTBT); poly[[9-(1-octylnonyl)-9H-carbazole-2,7-diyl]-2,5-thiophenediyl-2,1,3-benzothiadiazole-4,7-diyl-2,5-thiophenediyl] (PCDTBT); poly[(4,40-bis(2-ethylhexyl)dithieno [3,2-b:20,30-d]silole)-2,6-diyl-alt-(2,1,3-benzo-thiadiazole)-4,7-diyl] (PSBTBT); poly((4,8-bis(octyloxy)benzo(1,2-b:4,5-b′)dithiophene-2,6-diyl) (2-((dodecyloxy)carbonyl) thieno(3,4-b)thiophenediyl)) (PTB1); poly((4,8-bis(octyloxy)benzo(1,2-b:4,5-b′)dithiophene-2,6-diyl)(2-((ethylhexyloxy)carbonyl) thieno(3,4-b)thiophenediyl)) (PTB2); poly((4,8-bis(octyl)benzo(1,2-b:4,5-b′)dithiophene-2,6-diyl) (2-((ethylhexyloxy)carbonyl) thieno(3,4-b)thiophenediyl)) (PTB3); poly((4,8-bis-(ethylhexyloxybenzo(1,2-b:4,5-b′)dithiophene-2,6-diyl) (2-((octyloxy)carbonyl)-3-fluoro)thieno(3,4-b)thiophenediyl)) (PTB4); poly((4,8-bis(ethylhexyloxybenzo(1,2-b:4,5-b′)dithiophene-2,6-diyl)(2-((octyloxy)carbonyl) thieno(3,4-b)thiophenediyl)) (PTB5); poly((4,8-bis(octyloxy)benzo(1,2-b:4,5-b′)dithiophene-2,6-diyl)(2-((butyloctyloxy)carbonyl) thieno(3,4-b)thiophenediyl)) (PTB6); poly[[5-(2-ethylhexyl)-5,6-dihydro-4,6-dioxo-4H-thieno[3,4-c]pyrrole-1,3-diyl][4,8-bis[(2-ethylhexyl)oxy]benzo [1,2-b:4,5-b′]dithiophene-2,6-diyl]] (PBDTTPD); poly[1-(6-{4,8-bis[(2-ethylhexyl)oxy]-6-methylbenzo[1,2-b:4,5-b′]dithiophen-2-yl}-3-fluoro-4-methylthieno[3,4-b]thiophen-2-yl)-1-octanone] (PBDTTT-CF); or poly[2,1,3-benzothiadiazole-4,7-diyl-2,5-thiophenediyl (9,9-dioctyl-9H-9-silafluorene-2,7-diyl)-2,5-thiophenediyl] (PSiF-DBT). Other suitable materials include poly[5,7-bis (4-decanyl-2-thienyl) thieno[3,4-b]diathiazole-thiophene-2,5] (PDDTT); poly[2,3-bis(4-(2-ethylhexyloxy)phenyl)-5,7-di(thiophen-2-yl)thieno[3,4-b]pyrazine] (PDTTP); or polythieno[3,4-b]thiophene (PTT). In certain embodiments, suitable materials are copolymers derived from substituted or unsubstituted benzodithiophene monomers, such as the PTB1-7 series and PCPDTBT; or benzothiadiazole monomers, such as PCDTBT and PCPDTBT.

The acceptor material may include a fullerene or a fullerene derivative having a carbon cluster of at least 60 carbon atoms. In some embodiments, the acceptor material includes a fullerene or a fullerene derivative having a carbon cluster of 60 carbon atoms, a carbon cluster of 70 carbon atoms or a combination thereof. Suitable examples include phenyl-C-butyric-acid-methyl ester (PCBM) analogs such as phenyl-C₆₀-butyric-acid-methyl ester (PC₆₀BM), phenyl-C₇₁-butyric-acid-methyl ester (PC₇₀BM), phenyl-C₈₅-butyric-acid-methyl ester (PC₃₄BM), bis-adducts thereof, such as bis-PC₇₁BM, or indene mono-adducts thereof. In certain embodiments, the acceptor material includes a fullerene or a fullerene derivative having a carbon cluster of 70 carbon atoms, for example PC₇₀BM. Some other examples of acceptor materials include poly[(9,9-dioctylfluorenyl-2,7-diyl)-alt-(4,7-bis(3-hexylthiophen-5-yl)-2,1,3-benzothiadiazole)-2′,2″-diyl] (F8TBT) that may be used with the fullerene or the fullerene derivative.

In the operating mode, when an organic charge integrating device is irradiated with the electromagnetic radiation for a time period, the organic photoactive layer generates photo-excited charges and transports them to electrodes. These charges are accumulated in the pixels capacitors of the organic charge integrating device. Because of a substantial settling time after irradiating electromagnetic radiation and before reading-out accumulated charges, there is enough time to separate photo-excited charges (electron-hole pairs) and accumulate the charges in the pixel capacitors of the organic charge integrating devices. Without being bound by any theory, it is believed that there is enough time to transport and collect a substantial amount of charges (more than 90 percent of photo-excited charges) during each cycle of the frame time, and thus the performance (for example, quantum efficiency) of the organic charge integrating device is substantially insensitive to the thickness of the organic photoactive layer in a wide range (for example, from about 500 nanometers to about 3 microns). As used herein, the term “substantially insensitive” means that the thickness of the organic photoactive layer may have no or a little effect on the performance of the organic charge integrating device. In some embodiments, the quantum efficiency of the organic charge integrating device may change by less than 10 percent, and in some embodiments, less than 1 percent for a variation in thickness in a range from about 500 nanometers to about 3 microns of the organic photoactive layer.

Further, it has been observed by the inventors of the present disclosure that a thick organic photoactive layer (thickness ≧700 nanometers) is of comparatively good quality (that is, the number of defects are relatively lesser) than a thinner (thickness <700 nanometers) organic photoactive layer. These results are described in details below in the Example section. Furthermore, a thick organic photoactive layer (thickness >700 nanometers) that is a continuous film disposed on the TFT array, may provide comparatively good mechanical stability because of its improved strength than a thin organic photoactive layer (thickness <700 nanometers).

In some embodiments, the organic photoactive layer 106 having a thickness greater than 700 nanometers may be desirable because of its good quality and strength. In some embodiments, the organic photoactive layer 106 has a thickness in a range from 700 nanometers to about 3 microns. In some embodiments, the organic photoactive layer 106 has a thickness in a range from about 700 nanometers to about 2.5 microns. In some embodiments, the thickness of the organic photoactive layer 106 is in a range from about 800 nanometers to about 2 microns. In certain embodiments, the thickness of the organic photoactive layer 106 is in a range from about 850 nanometers to about 1.5 microns. An organic photoactive layer having a thickness greater than 3 microns may not be desirable. An organic photoactive layer having thickness from about 700 nanometers to about 3 microns may be sufficient for achieving desired quality (reduced defects) of the organic photoactive layer and performance (for example, quantum efficiency) of an organic charge integrating device including the organic photoactive layer. A thicker organic photoactive layer than needed (for example >3 microns) may degrade the performance (quantum efficiency) and contribute to increase in the cost of an organic charge integrating device.

Referring again to FIGS. 3-4, the scintillator layer 110 may include a phosphor material that is capable of converting incident radiation (for example, x-rays) to visible light. The wavelength region of light emitted by scintillator layer 110 may range from about 360 nanometers to about 830 nanometers. Suitable materials for the scintillator layer 110 include, but are not limited to, cesium iodide (CsI), thallium doped cesium iodide (CsI:Tl), terbium doped gadolinium oxysulfide, sodium iodide (NaI), lutetium oxides (LuₓO_{y}) or combinations thereof. In certain embodiments, the scintillator layer 110 includes thallium doped cesium iodide. Thallium doped cesium iodide generally has higher conversion efficiency than other materials.

The scintillator layer 110 can be applied using a deposition technique such as physical vapor deposition technique or thermal lamination of scintillator material pre-deposited onto a separate substrate (for example, a plastic substrate). In certain embodiments, the scintillator layer 110 is deposited on the second electrode layer 108 by physical vapor deposition technique. Another example of scintillator layer that may be used is a PIB (particle in binder) scintillator, where scintillating particles may be incorporated in a binder matrix material and flattened on a substrate. The scintillator layer 110 may be a monolithic scintillator or a pixelated scintillator array.

Non-limiting examples of materials for the planarization layer 112 include a polyimide, an acrylate, or a low solvent content silicone. Suitable materials for the barrier layer 114 may include an inorganic material such as silicon, a metal oxide, a metal nitride, or combinations thereof, where the metal is indium, tin, zinc, titanium, and aluminum. Non-limiting examples of metal nitrides and metal oxides include indium zinc oxide (IZO), indium tin oxide (ITO), silicon oxide, silicon nitride, silicon oxynitride, aluminum oxide, aluminum oxynitride, zinc oxide, indium oxide, tin oxide, cadmium tin oxide, cadmium oxide, magnesium oxide, or combinations thereof.

In some embodiments, an imaging system is also presented. The imaging system may include the organic charge integrating device as described previously. An organic charge integrating device according to some embodiments of the present disclosure may be used in imaging systems, for example, in conformal imaging having the organic charge integrating device in intimate contact with the imaging surface. For parts with internal structure, the organic charge integrating device may be rolled or shaped to contact an object or a part being imaged. Applications for the organic charge integrating devices, for example, organic x-ray detectors, according to some embodiments of the present disclosure, include security imaging; medical imaging; and industrial and military imaging for pipeline, fuselage, airframe and other tight access areas.

In some embodiments, an imaging system may include an x-ray imaging system. As shown in FIG. 6, the x-ray imaging system 200 includes an x-ray source 210 configured to irradiate an object 220 with x-ray radiation; an organic x-ray detector 230 (as described earlier), and a processor 240 operable to process data from the organic x-ray detector 230.

### EXAMPLES

Light imagers were fabricated and tested as described below. Performance of an organic x-ray detector (OXRD) was predetermined based on the performance of the corresponding light imager.

### Example 1: Fabrication of Light Imagers

A blend was prepared in the nitrogen glovebox by dissolving a donor polymer material with PC₇₀BM acceptor material using 1:1 weight ratio at 20-80 mg/mL into chlorobenzene.

A thin film transistor (TFT) substrate having a TFT array pre-coated with an indium titanium oxide (ITO) anode layer was used as a substrate, where the ITO anode layer is connected to a source and a drain of the TFT. A proprietary charge blocking layer including a crosslinkable polymer of about 100 nanometers was coated atop the ITO anode layer of the TFT substrate. The charge blocking layer was then cured under UV exposure. An organic photoactive layer composed of the blend (prepared as discussed above) was then deposited onto the organic electron blocking layer inside a N₂ purged glove box followed by baking for 1 hour at about 75 degrees Celsius. An ITO cathode layer was deposited by sputtering on the photoactive layer.

### Example 2: Light Imager 1

A light imager 1 was fabricated according to the same process as described in example 1. The organic photoactive layer was coated using a slot-die coater. The thickness of the organic photoactive layer was varied in various regions by the amount of the blend applied. The organic photoactive layer had variable thickness in a range from about 500 nanometers to about 2.5 microns.

### Example 3: Light Imagers (2-5)

Four light imagers (2-5) were fabricated according to the above process as described in example 1. The organic photoactive layers of thicknesses as given in Table 1 for each light imager (2-5) were deposited by spin coating method. The light imagers 4 and 5 were comparative light imagers having organic photoactive layers of thicknesses less than 700 nanometers, to the light imagers 2 and 3 having organic photoactive layers of thicknesses greater than 700 nanometers.

### Example 4: Testing of Light Imager 1

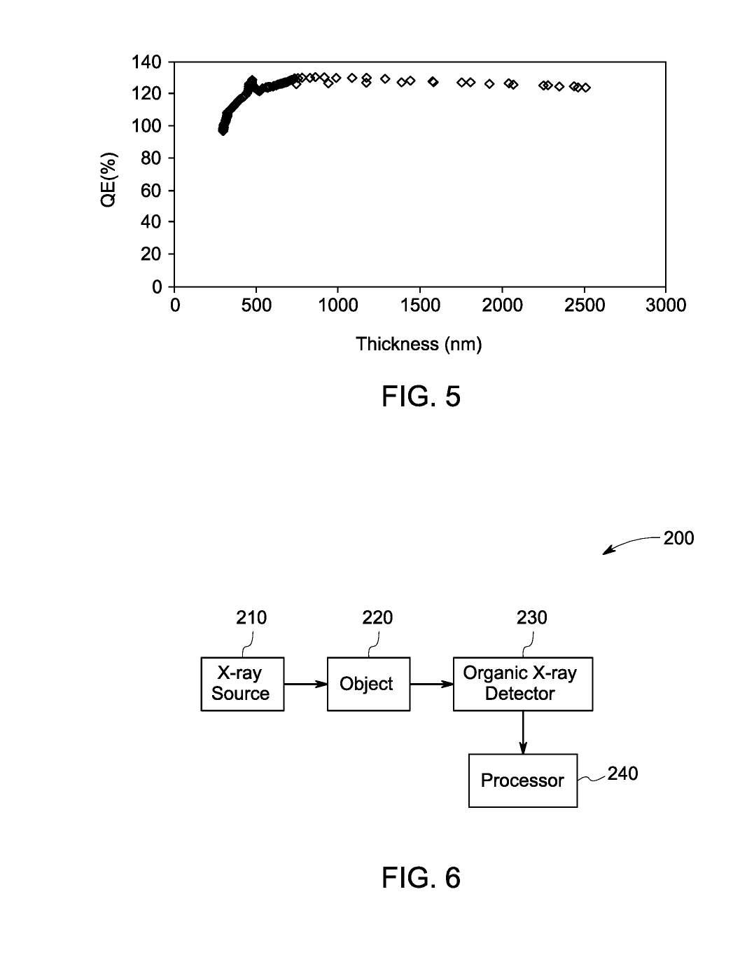

Performance (quantum efficiency) of the light imager 1 was measured using an imager functional tester in a timing mode. FIG. 5 is a graph showing quantum efficiency of the light imager 1 as a function of the thickness of the corresponding organic photoactive layer. The graph shows comparable quantum efficiencies of the light imager 1 in various regions of the organic photoactive layer with the thicknesses in a range from about 700 nanometers to about 2.5 microns. Accordingly, it was observed that the performance of the light imager 1 was not affected by the thickness in a wide range from about 700 nanometers to about 2.5 microns.

### Example 4: Testing of Light Imagers (2-5)

Defects in an organic photoactive layer were predicted by measuring a leakage current in the corresponding organic photodiode. In a light imager, a pixel was considered a defect when a leakage current of an organic photodiode at the pixel exceeds a predefined current value. The leakage currents in organic photodiodes of four light imagers (2-5) of example 3 were separately measured by accumulating charges in each light imager (2-5) for a frame time in a dark environment (without irradiating light), and evaluated with respect to a predefined current value at each pixel.

The four light imagers (2-5) were characterized using an imager functional tester under same timing mode.

Table 1 shows defects in the organic photoactive layers and performance (quantum efficiency and leakage current) of the four light imagers (2-5).

TABLE 1
Performance of light imagers

| | Thickness of the | Number of defects in | | Leakage |
|---|---|---|---|---|
| Light | organic photoactive | the organic | QE | current |
| imager | layer (nm) | photoactive layer | (%) | (pA/cm²) |
| 2 | 941 | 1452 | 124 | 4.6 |
| 3 | 888 | 2817 | 127 | 3.1 |
| 4 | 696 | 5919 | 127 | 3.2 |
| 5 | 544 | 5044 | 123 | 5.1 |

As shown in Table 1, the light imagers (2-5) having different thicknesses (>500 nanometers) of organic photoactive layers show comparatively similar quantum efficiencies and leakage currents. Moreover, as shown in Table 1, the thicker organic photoactive layers of light imagers 2 and 3 have significantly lesser (half or one third) defects than the defects in the relatively thinner organic photoactive layers of the comparative light imagers 4 and 5. These results clearly indicate that the light imagers 2 and 3 include organic photoactive layers with lower number of defects by using thicker organic photoactive layers (>700 nanometers) when compared to the comparative light imagers 4 and 5 (having organic photoactive layers of thickness <700 nanometers), while achieving the desired performance characteristics.

From above examples, it is concluded that the organic charge integrating devices having thick organic photoactive layers (thickness >700 nanometers) are able to provide quantum efficiencies-125%.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An organic charge integrating device, comprising:
a thin film transistor (TFT) array;
a first electrode layer disposed on the TFT array;
an organic photoactive layer disposed on the first electrode layer, wherein the organic photoactive layer has a thickness in a range from about 700 nanometers to about 3 microns; and
a second electrode layer disposed on the organic photoactive layer.

2. The organic charge integrating device according to claim 1, wherein the organic photoactive layer has a thickness in a range from 750 nanometers to about 2.5 microns.

3. The organic charge integrating device according to claim 1, wherein the organic photoactive layer has a thickness in a range from 800 nanometers to about 2 microns.

4. The organic charge integrating device according to claim 1, wherein the organic photoactive layer comprises a donor material and an acceptor material.

5. The organic charge integrating device according to claim 4, wherein the acceptor material comprises a fullerene or a fullerene derivative having a carbon cluster of at least 60 carbon atoms.

6. The organic charge integrating device according to claim 5, wherein the fullerene or the fullerene derivative comprises a carbon cluster of 60 carbon atoms, a carbon cluster of 70 carbon atoms or a combinations thereof.

7. The organic charge integrating device according to claim 4, wherein the donor material comprises a low bandgap polymer.

8. The organic charge integrating device according to claim 7, wherein the low bandgap polymer comprises units derived from substituted or unsubstituted thienothiophene, benzodithiophene, benzothiadiazole, pyrrolothiophene, carbazole, or combinations thereof.

9. The organic charge integrating device according to claim 1, further comprising a scintillator layer disposed on the second electrode.

10. The organic charge integrating device according to claim 9, wherein the scintillator layer comprises cesium iodide, thallium doped cesium iodide, terbium doped gadolinium oxysulfide, sodium iodide, lutetium oxides, or combinations thereof.

11. An organic x-ray detector, comprising:
a thin film transistor (TFT) array;
a first electrode layer disposed on the TFT array;
an organic photoactive layer comprising a fullerene or a fullerene derivative having a carbon cluster of at least 60 carbon atoms, disposed on the first electrode layer, wherein the organic photoactive layer has a thickness in a range from 750 nanometers to about 2.5 microns;
a second electrode layer disposed on the organic photoactive layer; and
a scintillator layer disposed on the second electrode layer.

12. The organic x-ray detector according to claim 11, wherein the scintillator layer comprises thallium doped cesium iodide.

13. The organic x-ray detector according to claim 11, wherein the organic photoactive layer has a thickness in a range from 800 nanometers to about 2 microns.

14. The organic x-ray detector according to claim 11, wherein the fullerene or the fullerene derivative comprises a carbon cluster of 60 carbon atoms, a carbon cluster of 70 carbon atoms or a combination thereof.

15. An imaging system comprising an organic x-ray detector comprising:
a thin film transistor (TFT) array;
a first electrode layer disposed on the TFT array;
an organic photoactive layer comprising a fullerene or a fullerene derivative having a carbon cluster of at least 60 carbon atoms, disposed on the first electrode layer, wherein the organic photoactive layer has a thickness in a range from 750 nanometers to about 2.5 microns;
a second electrode layer disposed on the organic photoactive layer; and
a scintillator layer disposed on the second electrode layer.
